(19) United States
(12) Patent Application Publication
(10) Pub. No.: US 2016/0197545 A1
(43) Pub. Date: Jul. 7, 2016

(54) CURRENT DETECTOR AND POWER CONVERSION DEVICE

(71) Applicant: FUJI ELECTRIC CO., LTD., Kawasaki-shi (JP)

(72) Inventors: Yuji NEMOTO, Tokyo (JP); Ryuji YAMADA, Tokyo (JP)

(73) Assignee: FUJI ELECTRIC CO., LTD., Kawasaki-shi (JP)

(21) Appl. No.: 15/067,320

(22) Filed: Mar. 11, 2016

Related U.S. Application Data
(63) Continuation of application No. PCT/JP2014/056108, filed on Mar. 10, 2014.

(51) Int. Cl. H02M 1/08; G01R 19/00; G01R 19/32

(52) U.S. Cl. CPC H02M 1/08; G01R 19/32; G01R 19/0092; H02M 2001/0009

(57) ABSTRACT

A current detector for detecting a main circuit current of an inductor connected to a switching element whose operation generates that current. The inductor includes main and auxiliary windings equal in numbers of turns and connected to the detector so as to cancel out electromotive forces generated by the operation in the windings. The detector includes a voltage detection unit having two input terminals. One end of each winding is connected to a different one of these terminals. The voltage detection unit detects a voltage difference between the connected ends. The detector also includes a temperature detection unit detecting a temperature of the main winding, and a current calculation unit correcting a main winding resistance using the detected temperature and calculating a current as the main circuit current, using the corrected resistance and an average detected voltage calculated from sampled values of the detected voltage using a sampling frequency.

### CROSS-REFERENCE TO RELATED APPLICATION

This is a continuation application of International Application number PCT/JP2014/056108, which was filed on Mar. 10, 2014 and designated the United States. The disclosure of this earlier application is incorporated herein by reference.

### BACKGROUND OF THE INVENTION

1. Technical Field

The present invention relates to a current detector, which detects a current flowing through an inductor, and a power conversion device which carries out power conversion by controlling a semiconductor switching element on/off using a current detection value detected by the current detector.

2. Background Art

As a chopper which boosts or bucks a direct current voltage, there is one which detects a current flowing through an inductor in which to store energy, and controls a semiconductor switching element on/off based on the current detection value of the detected current.

FIG. 5 shows a common buck chopper including the current detection function of a main circuit. In FIG. 5, a semiconductor switching element 12, such as a MOSFET (Metal-Oxide-Semiconductor Field-Effect Transistor), and a diode 13 are connected in series to each other, across a direct current power source 11, in a reverse direction. Also, an inductor 14, a current detection section 15, and a smoothing capacitor 16 are connected in series across the diode 13, and a load 17 is connected across the smoothing capacitor 16. 12d denotes a parasitic diode.

With the buck chopper, the semiconductor switching element 12 is turned on to store energy in the inductor 14. Also, the semiconductor switching element 12 is turned off to emit the stored energy of the inductor 14, and the energy is supplied to the smoothing capacitor 16 via the diode 13, thereby realizing a buck operation.

A control circuit 30 carries out a feedback control such that the semiconductor switching element 12 is turned on/off using the detection value of a current (a main circuit current) I_{L} output from the current detection section 15 and the detection value of an output voltage Vₒᵤₜ obtained from the smoothing capacitor 16, thus matching the output voltage Vₒᵤₜ with a command value.

As the current detection section 15, there is a circuit using, for example, a shunt resistance and a Hall CT (Current-Transformer), wherein the current I_{L} is converted to a voltage value by these parts.

Meanwhile, as a heretofore known technology which detects the current of an inductor, for example, JP-A-3-178555 (at page 3, an upper right column, line 17 to a lower right column, line 20, FIG. 1, and so on) shows a method whereby the inductor includes a main winding and an auxiliary winding, and with one end of the auxiliary winding being connected to one end of the main winding of the inductor, the voltage between the other end of the auxiliary winding and the other end of the main winding is detected.

FIG. 6 is a circuit diagram when the heretofore known technology described in JP-A-3-178555 is applied to the current detection section 15 in FIG. 5, wherein 141 is a main winding of the inductor 14, 142 is an auxiliary winding, and 20 is a voltage detection section. The main winding 141 and the auxiliary winding 142 are wound in the same direction and are also equal in the number of turns. a and b are one end and the other end of the main winding 141, and a′ and b′ are one end and the other end of the auxiliary winding 142.

Herein, the main winding 141 is connected in series to a main circuit (between the output side of the semiconductor switching element 12 and one end of the smoothing capacitor 16 in FIG. 5). Also, the one end a′ of the auxiliary winding 142 is connected to the main circuit, and the other end b′ is connected to the voltage detection section 20, together with the other end b of the main winding 141.

In FIG. 6, as the current I_{L} flows through the main winding 141 and does not flow through the auxiliary winding 142 when the input impedance of the voltage detection section 20 is large enough, a voltage drop (R·I_{L}) caused by winding resistance R of the main winding 141 occurs in only the main winding 141.

Also, an alternating voltage of a size of (L·dI_{L}/dt) is generated across the main winding 141 by the switching operation of the unshown semiconductor switching element. L is the inductance of the main winding 141.

Herein, as the main winding 141 and the auxiliary winding 142 are in the same relationship as the primary winding and secondary winding of a transformer with a winding turn ratio of 1:1, electromotive forces of a size equal to the alternating voltage (L·dI_{L}/dt) generated across the main winding 141 are generated across the auxiliary winding 142 in the same polarity.

Consequently, the voltage between the other ends b and b′ of the main winding 141 and auxiliary winding 142, the one ends a and a′ of which are of the same potential, exhibits only the voltage drop (R·I_{L}) caused by the current I_{L} flowing through the main winding 141, and this voltage is detected by the voltage detection section 20. Therefore, by measuring the winding resistance R of the main winding 141 in advance, the control circuit can obtain the current I_{L} from the relationship of a voltage detection value V (=R·I_{L}) detected by the voltage detection section 20.

### SUMMARY OF THE INVENTION

As well known, as the winding resistance value of an inductor depends on the temperature of a winding material (copper), when the winding temperature reaches a high temperature, the winding resistance also increases, as when power is being supplied to a heavy load. For example, when the temperature rises by 80[K], the winding resistance R becomes as high as 1.3 times, meaning that the heretofore known technology of JP-A-3-178555 on the premise that the winding resistance R is a fixed value is not practical because the margin of error of the current detection value increases significantly.

Therefore, a problem to be solved by the invention is to provide a current detector, which can accurately detect the size of a main circuit current flowing through an inductor without being affected by the winding temperature of the inductor, and a power conversion device using the current detector.

In order to solve the problem, the invention relates to a current detector which detects a main circuit current which flows through an inductor by a switching operation of a semiconductor switching element, the inductor including a main winding and an auxiliary winding which are equal in the number of turns, and which is connected in such a way that electromotive forces generated in the main winding and auxiliary winding by the switching operation are cancelled out and to a power conversion device using the current detector.

Further, a current detector includes a voltage detection section to the input terminal of which are connected the other ends of the main winding and auxiliary winding, one end of each of which is connected to a main circuit line, and which detects only the voltage between the other end of the main winding and the other end of the auxiliary winding.

Furthermore, the current detector includes a temperature detection section, which detects the temperature of the main winding, and a current computing section which corrects the winding resistance of the main winding based on the temperature detected by the temperature detection section, and computes the main circuit current, which flows through the main winding, using the corrected winding resistance and a voltage detection value detected by the voltage detection section.

It is desirable that the current computing section computes the main circuit current using the voltage detection value sampled in synchronism with the switching operation of the semiconductor switching element.

Also, the current detector is such that the main winding is configured by connecting a plurality of winding elements in parallel, and that the number of winding elements of the auxiliary winding is set to be equal to or less than the number of parallel connections of the main winding.

Furthermore, the diameter of the winding elements of the auxiliary winding can be set to be smaller than the diameter of the winding elements of the main winding. The current detector is such that the auxiliary winding of the inductor is substituted by a secondary winding of a transformer.

That is, the invention includes a transformer with a primary winding that is connected in parallel to an inductor and a secondary winding having the same turn ratio as the primary winding. The inductor is connected in series to a main circuit line. Also, the invention includes a voltage detection section having first and second input terminals. The first input terminal is connected to one end of the inductor and the second input terminal is connected to one end of the secondary winding. The other end of each of the inductor and the secondary winding is connected to the main circuit line so that electromotive forces generated in the inductor and the secondary winding by the switching operation are cancelled out, and the voltage detection section detects only the voltage between the other end of the inductor and the other end of the secondary winding.

Furthermore, the invention includes a temperature detection section, which detects the temperature of the inductor, and a current computing section which corrects the winding resistance of the inductor based on the detected temperature, and computes the main circuit current, which flows through the inductor, using the corrected winding resistance and a voltage detection value detected by the voltage detection section.

Also, a power conversion device converts direct current power or alternating current power by controlling the switching operation of the semiconductor switching element using a current detection value detected by the current detector.

According to the invention, when the current detector measures the main circuit current flowing through the inductor based on a voltage drop, temperature of the inductor's main winding is taken into account to avoid an error that would otherwise occur if a resistance of the main winding were assumed to have a fixed value, thereby significantly improving the accuracy of the current detection.

### BRIEF DESCRIPTION OF THE DRAWINGS

FIG. 1A is a configuration diagram showing a first embodiment of the invention.

FIG. 1B is a circuit diagram of FIG. 1A.

FIG. 2 is a waveform diagram.

FIG. 3 is a circuit diagram showing a modification example of the first embodiment of the invention.

FIG. 4 is a circuit diagram showing a second embodiment of the invention.

FIG. 5 is a circuit diagram of a common buck chopper.

FIG. 6 is a circuit diagram of a heretofore known technology described in JP-A-3-178555.

### DETAILED DESCRIPTION OF THE INVENTION

Hereafter, a description will be given, along the drawings, of embodiments of the invention.

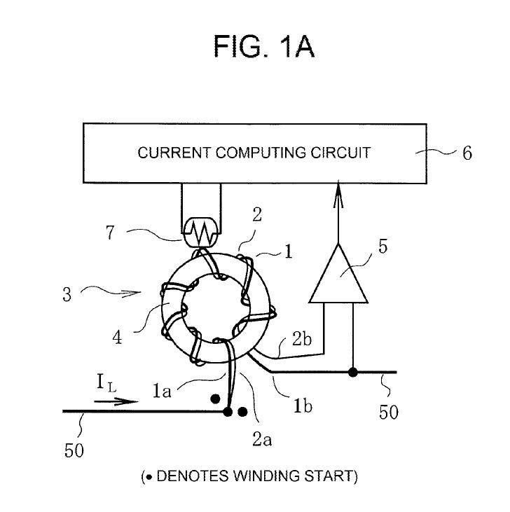

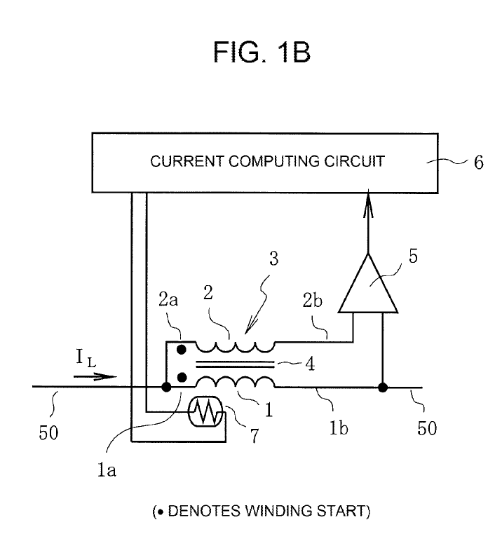

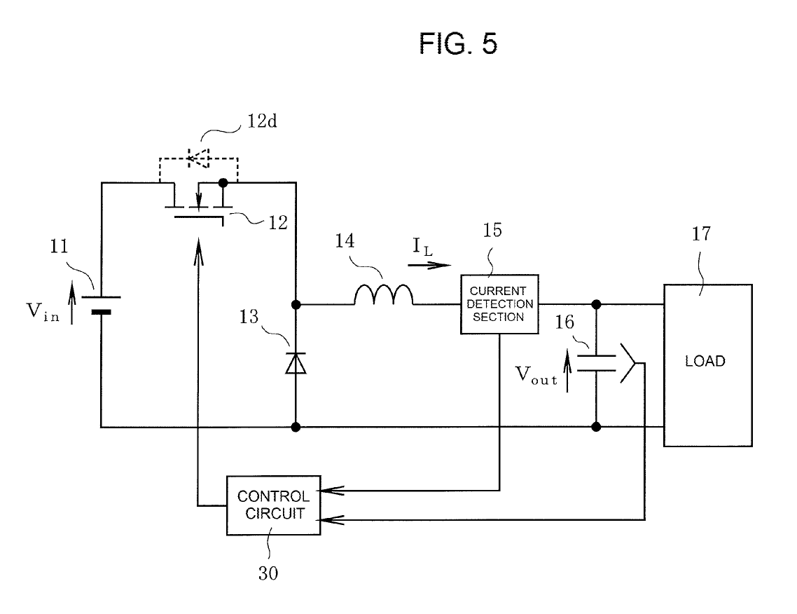

Firstly, FIG. 1A is a configuration diagram of a current detector according to a first embodiment of the invention, and FIG. 1B is a circuit diagram thereof. The current detector is connected between the output terminal of a semiconductor switching element 12 and one end of a smoothing capacitor 16, for example, as shown in FIG. 5, and is used to detect a current (a main circuit current) I_{L} flowing through an inductor, switch the semiconductor switching element 12 with a control circuit 30, and control an output voltage Vₒᵤₜ in accordance with a command value.

In FIGS. 1A and 1B, a main winding 1 and an auxiliary winding 2, which are equal in the number of turns, are wound in the same direction on a core 4 of an inductor 3. One ends 1a and 2a of the main winding 1 and auxiliary winding 2, at which winding starts, are connected to a main circuit line 50, and the main circuit line 50 is connected to the output side of a power conversion device, as shown in FIG. 5. Also, the other ends 1b and 2b of the main winding 1 and auxiliary winding 2, at which winding ends, are connected to the input side (first and second input terminals) of a voltage detection section 5 which detects and amplifies the voltage between the other ends 1b and 2b.

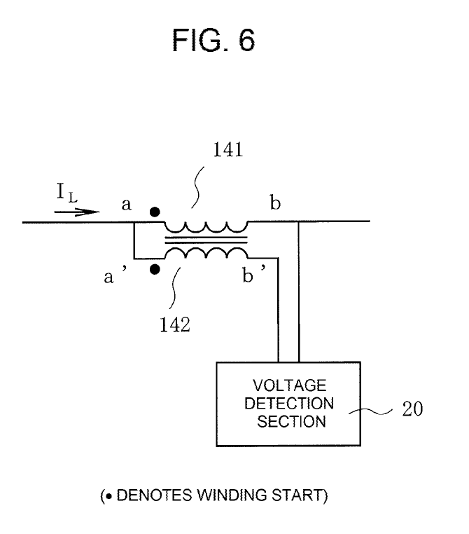

As the main winding 1 and the auxiliary winding 2 are wound in the same direction and are also equal in the number of turns, respective alternating voltages (L·dI_{L}/dt) generated across the main winding 1 and auxiliary winding 2 as a result of a switching operation of the semiconductor switching element are equal in size and polarity, in the same way as in a main winding 141 and auxiliary winding 142 of FIG. 6. That is, as is clear from FIG. 1B, the relationship of connection between the main winding 1 and auxiliary winding 2 and the voltage detection section 5 is the same as the relationship of connection between the main winding 141 and auxiliary winding 142 and a voltage detection section 20 in FIG. 6.

Also, 7 is a temperature detection element, such as a thermistor, which detects the temperature of the main winding 1, and the output of the temperature detection element 7 is input into a current computing circuit (current calculating circuit) 6, such as a microcomputer, together with the output of the voltage detection section 5.

The current computing circuit 6 includes, as a first function, the function of correcting the winding resistance of the main winding 1 in response to the temperature of the main winding 1 detected by the temperature detection element 7, and includes, as a second function, the function of correcting a voltage detection value, detected by the voltage detection section 5, using the corrected winding resistance. With the second function, it is also possible to correct an error resulting from the imbalance, between an increase and decrease in the voltage detection value V, caused due to the leakage inductance of the main winding 1 when in switching operation.

Next, a description will be given of an operation of the first embodiment. When the current I_{L} flows by the switching operation of the semiconductor switching element, electromotive forces (L·dI_{L}/dt) generated in the main winding 1 and auxiliary winding 2 are cancelled out by the same principle as in FIG. 6, and a voltage V depending on only winding resistance R of the main winding 1 is detected by the voltage detection section 5 and input into the current computing circuit 6. At the same time as this, the temperature of the main winding 1 is detected by the temperature detection element 7 and input into the current computing circuit 6.

Herein, as the temperature-resistance characteristics of the main winding 1 is known, the current computing circuit 6 computes the current I_{L} from the relationship of V=R·I_{L} using the winding resistance R corrected in response to the detected temperature of the main winding 1 and the voltage detection value V detected by the voltage detection section 5. By so doing, it is possible to resolve a measurement error resulting from a difference in winding temperature.

When using a thermistor as the temperature detection element 7, an error can also occur due to the non-linearity of the temperature characteristics of the thermistor. However, it is easy for the current computing circuit 6 to correct the winding resistance R, including the non-linearity, and it is possible to significantly reduce a computation error of the current I_{L}.

However, as an imbalance occurs between the increase and decrease in the voltage detection value V, due to the leakage inductance of the main winding 1, as a result of the switching operation, the imbalance causes an error in an average value V_{average} of the voltage detection value V.

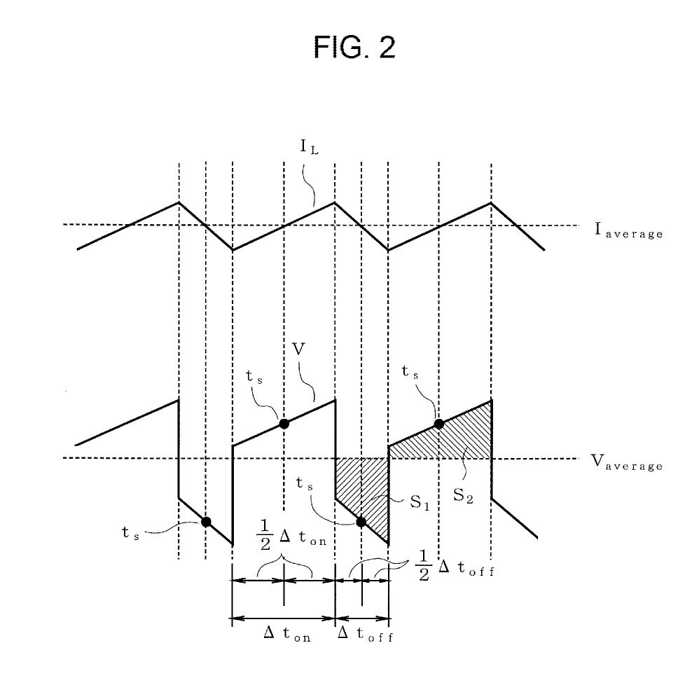

FIG. 2 is a schematic waveform diagram of the current I_{L} and voltage detection value V in the embodiment, and as areas S₁ and S₂ of the hatched portions in the waveform of the voltage detection value V depend on the ratio of the exciting inductance and leakage inductance of the main winding 1, on the conduction ratio (on-duty) of the semiconductor switching element, and on the voltage across a reactor 3, it is possible to infer the areas S₁ and S₂ by way of the computation of the current computing circuit 6.

Herein, the information on the conduction ratio of the semiconductor switching element and the voltage across the reactor 3 can be obtained from the control circuit, but as for the inductance component of the main winding 1, there is fear that as the variability among the individuals exists with respect to a design value, it is not possible to obtain any high-precision value.

Therefore, in the embodiment, the waveform of the voltage detection value V is observed while being sampled at a frequency twice a switching frequency, and the average value V_{average} is computed, with the conduction ratio of the semiconductor switching element taken into account, utilizing the fact that the areas S₁ and S₂ become equal in the observed waveform. By so doing, it is possible to obtain the average value V_{average} with no error without being affected by the leakage inductance of the main winding 1.

tₛ in FIG. 2 denotes a sampling timing, and the timing corresponds to the midpoint of each of an on-period Δtₒₙ and off-period Δt_{off} of the semiconductor switching element.

The current computing circuit 6 only has to compute the current I_{L} (an average value I_{average} thereof), from the relationship of V=R·I_{L}, using the thus detected average value V_{average} and temperature-corrected winding resistance R.

When providing the control circuit (a microcomputer), which controls the semiconductor switching element in accordance with a predetermined conduction ratio, with the function of the current computing circuit 6, software simply has to be added, and it is not necessary to separately provide, for example, a dedicated circuit which takes in the conduction ratio.

In this way, according to the embodiment, it is possible to detect the size of the main circuit current I_{L}, with high precision and at high speed, in order to control the semiconductor switching element of the power conversion device.

When using a current detection value for only a low-speed control and current monitoring of the power conversion device, a lowpass filter only has to be connected to the output side of the voltage detection section 5, thus eliminating the effect of the leakage inductance of the main winding 1.

In the embodiment, as no main circuit current flows through the auxiliary winding 2 when the input impedance of the voltage detection section 5 is large, it is possible to suppress an increase in cost by using a wire, smaller in diameter than the main winding 1, as the auxiliary winding 2.

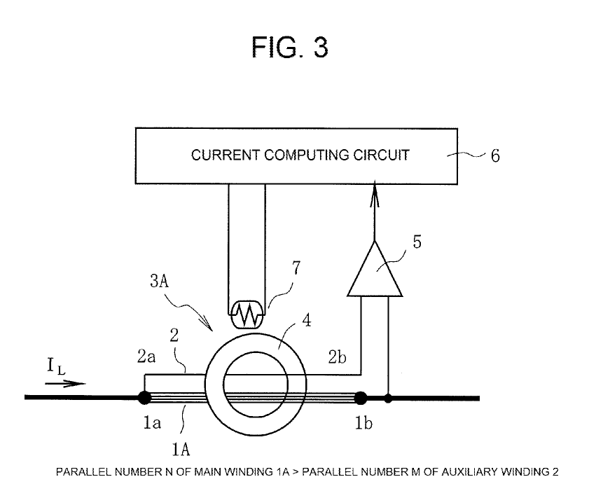

Also, it is often the case that an inductor for large current is configured by connecting a plurality of main windings in parallel. In this case, as a modification example, with one of a plurality of winding elements of a main winding 1A, which are connected in parallel to each other, as the auxiliary winding 2, the other end of the auxiliary winding 2 may be connected to the voltage detection portion 5, as in a one-turn inductor 3A shown in FIG. 3. In this case, the auxiliary winding 2 may be configured by connecting a plurality of winding elements in parallel, and in any case, there only has to be the relationship of a parallel number N of winding elements of the main winding 1A>a parallel number M of winding elements of the auxiliary winding 2.

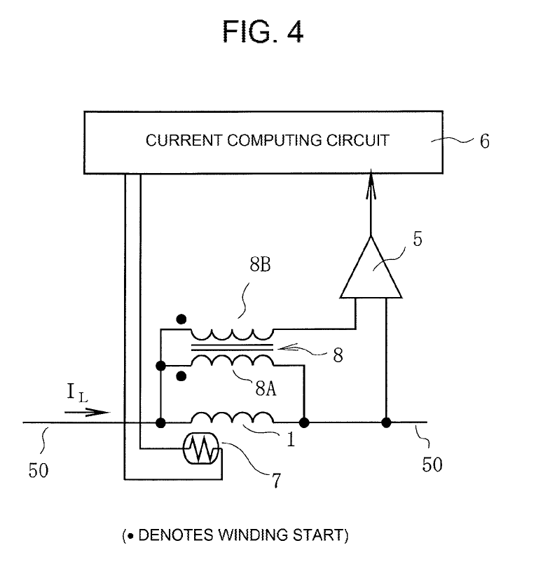

Next, FIG. 4 is a circuit diagram showing a second embodiment of the invention. In FIG. 4, the same signs are given to component portions the same as those of FIGS. 1A, 1B, and 3, and hereafter, a description will be given centering on the differences.

In the first embodiment, the altered inductors 3 and 3A are used, but in the second embodiment, the need to alter the inductor itself is eliminated.

That is, in FIG. 4, the inductor connected in series to the main circuit line 50 is configured of only the main winding 1. Also, 8 is a transformer with a winding turn ratio of 1:1, wherein a primary winding 8A of the transformer 8 is connected in parallel to the main winding 1. Furthermore, one end of a secondary winding 8B is connected to the one end of the main winding 1, and the other end of the secondary winding 8B is connected to one input terminal of the voltage detection section 5. The other end of the main winding 1 is connected to the other input terminal of the voltage detection section 5, in the same way as in the first embodiment.

According to the second embodiment, by utilizing the secondary winding 8B of the transformer 8, which is connected in parallel to the inductor, as the auxiliary winding, it is possible to obtain the same working effects as in the first embodiment even without altering the inductor itself.

### INDUSTRIAL APPLICABILITY

The invention can be utilized for various power conversion devices, such as a boost chopper, a buck chopper, an inverter, and a converter, which convert direct current power or alternating current power by controlling the semiconductor switching element on/off using the current detection value obtained by the current detector according to each embodiment. Also, the phase type (a single phase or multiple phases) of the power conversion devices is not particularly limited either.

What is claimed is:

1. A current detector for detecting a main circuit current flowing through an inductor connected to a semiconductor switching element via a main circuit line, the main circuit current being generated by a switching operation of the semiconductor switching element, the inductor including a main winding and an auxiliary winding that are equal in a total number of turns and connected to the current detector so as to cancel out electromotive forces generated by the switching operation in the main winding and the auxiliary winding, the current detector comprising:
a voltage detection unit including a first input terminal connected to one end of the main winding and a second input terminal connected to one end of the auxiliary winding, the voltage detection unit being configured to detect a voltage difference between the one end of the main winding and the one end of the auxiliary winding as a detected voltage;
a temperature detection unit configured to detect a temperature of the main winding; and
a current calculation unit configured to correct a winding resistance of the main winding based on the temperature detected by the temperature detection unit, and calculate a current detection value as the main circuit current, using a corrected winding resistance and an average value of the detected voltage, the average value of the detected voltage being calculated from sampled values of the detected voltage using a sampling frequency that is twice a switching frequency of the semiconductor switching element.

2. The current detector according to claim 1, wherein
the main winding and the auxiliary winding are each configured by connecting a plurality of winding elements in parallel, and
a total number of winding elements of the auxiliary winding is set to be smaller than a total number of parallel connections of the winding elements of the main winding.

3. The current detector according to claim 1, wherein diameters of the winding elements of the auxiliary winding are set to be smaller than diameters of the winding elements of the main winding.

4. The current detector according to claim 2, wherein diameters of the winding elements of the auxiliary winding are set to be smaller than diameters of the winding elements of the main winding.

5. A power conversion device configured to convert one of direct electric power and alternating electric power to one of an arbitrary current and an arbitrary voltage by controlling the switching operation of the semiconductor switching element using the current detection value detected by the current detector according to claim 1.

6. A power conversion device configured to convert one of direct electric power and alternating electric power to one of an arbitrary current and an arbitrary voltage by controlling the switching operation of the semiconductor switching element using the current detection value detected by the current detector according to claim 2.

7. A current detector for detecting a main circuit current flowing through an inductor connected to a main circuit line in series, the main circuit current being generated by a switching operation of a semiconductor switching element connected to the inductor via the main circuit line, the current detector comprising:
a transformer including a primary winding and a secondary winding each connected in parallel to the inductor, a secondary winding having a same winding turn ratio as the primary winding;
a voltage detection unit including a first input terminal connected to one end of the inductor via the main circuit line and a second input terminal connected to one end of the secondary winding so as to cancel out electromotive forces generated by the switching operation in the inductor and the secondary winding, the voltage detection unit being configured to detect a voltage difference between the one end of the inductor and the one end of the secondary winding as a detected voltage;
a temperature detection unit configured to detect the temperature of the main winding; and
a current calculation unit configured to correct the winding resistance of the inductor based on the temperature detected by the temperature detection unit, and calculate a current detection value as the main circuit current, using the corrected winding resistance and the detected voltage.

8. A power conversion device configured to convert one of direct electric power and alternating electric power to one of an arbitrary current and an arbitrary voltage by controlling the switching operation of the semiconductor switching element using the current detection value detected by the current detector according to claim 7.
